(19) United States
(12) Patent Application Publication
(10) Pub. No.: US 2026/0321458 A1
(43) Pub. Date: Oct. 15, 2026

(54) ROUTING STRUCTURE

(71) Applicant: Yazaki Corporation, Tokyo (JP)

(72) Inventor: Yukihiro KAWAMURA, Makinohara-shi (JP)

(73) Assignee: Yazaki Corporation, Tokyo (JP)

(21) Appl. No.: 19/462,480

(22) Filed: Jan. 28, 2026

(30) Foreign Application Priority Data
Mar. 18, 2025 (JP) 2025-043190

(51) Int. Cl. H01B 7/295; B60R 16/02

(52) U.S. Cl. CPC H01B 7/295; B60R 16/0215

(57) ABSTRACT

The routing structure according to an embodiment is an in-vehicle routing structure. The routing structure includes a first routing member and a second routing member. The first routing member includes a first conductor portion made of copper or a copper alloy and a first fire-resistant insulating portion covering an outer periphery of the first conductor portion. The second routing member includes a second conductor portion made of aluminum or an aluminum alloy, and a second fire-resistant insulating portion covering an outer periphery of the second conductor portion. The second routing member is electrically connected to the first routing member.

### BACKGROUND OF THE INVENTION

### Field of the Invention

An embodiment of the present invention relates to a routing structure.

Priority is claimed on Japanese Patent Application No. 2025-043190 filed in Japan on Mar. 18, 2025, the content of which is incorporated herein by reference.

### Description of Related Art

A routing member having a fire-resistant structure is known.

### PRIOR ART DOCUMENT

### Patent Literature

Patent Literature 1: Japanese Unexamined Patent Application, First Publication No. 2025-006266

### SUMMARY OF THE INVENTION

The in-vehicle routing structure is expected to be further reduced in weight.

An embodiment provides a routing structure that can achieve weight reduction.

The routing structure according to the embodiment is an in-vehicle routing structure. The routing structure includes a first routing member and a second routing member. The first routing member includes a first conductor portion made of copper or a copper alloy and a first fire-resistant insulating portion covering an outer periphery of the first conductor portion. The second routing member includes a second conductor portion made of aluminum or an aluminum alloy, and a second fire-resistant insulating portion covering an outer periphery of the second conductor portion. The second routing member is electrically connected to the first routing member.

In accordance with one embodiment, it is possible to reduce the weight of the routing structure.

### BRIEF DESCRIPTION OF THE DRAWINGS

FIG. 1 is a view illustrating an example of a vehicle on which a routing structure according to an embodiment is mounted;

FIG. 2 is a perspective view illustrating a routing member according to the embodiment;

FIG. 3 is a cross-sectional view taken along line F3-F3 of the routing member illustrated in FIG. 2;

FIG. 4 is a cross-sectional view taken along line F3-F3 of the routing member illustrated in FIG. 2;

FIG. 5 is a cross-sectional view illustrating an example of a fire-resistant insulating portion according to the embodiment;

FIG. 6 is a cross-sectional view illustrating an example of the fire-resistant insulating portion according to the embodiment;

FIG. 7 is a cross-sectional view illustrating an example of the fire-resistant insulating portion according to the embodiment; and

FIG. 8 is a cross-sectional view illustrating an example of the fire-resistant insulating portion according to the embodiment.

### DETAILED DESCRIPTION OF THE INVENTION

Hereinafter, an embodiment will be described with reference to the drawings. In the following description, configurations having the same or similar functions are denoted by the same reference numerals. Therefore, redundant descriptions of these configurations may be omitted. The configurations described below are not meant to limit the scope of the present disclosure.

In the present disclosure, terms are defined as follows. The term “connection” is not limited to a mechanical connection and may include an electrical connection. That is, the term “connection” is not limited to a case where two elements that are connection targets are directly connected and may include a case where two elements that are connection targets are connected with another element interposed therebetween.

In the present disclosure, an X direction, a Y direction, and a Z direction are defined as follows. The X direction is an extension direction of a first extension portion 53a of a second routing member 50B (described later). The Y direction is the width direction of the first extension portion 53a of the second routing member 50B. The Z direction is the thickness direction of the first extension portion 53a of the second routing member 50B. In the following description, the horizontal direction and the up, down, left, and right directions are based on the posture of the second routing member 50B in use (for example, when mounted on the vehicle V). However, these expressions are for convenience of description and do not limit the posture of the usage state.

### 1. Configuration of Vehicle

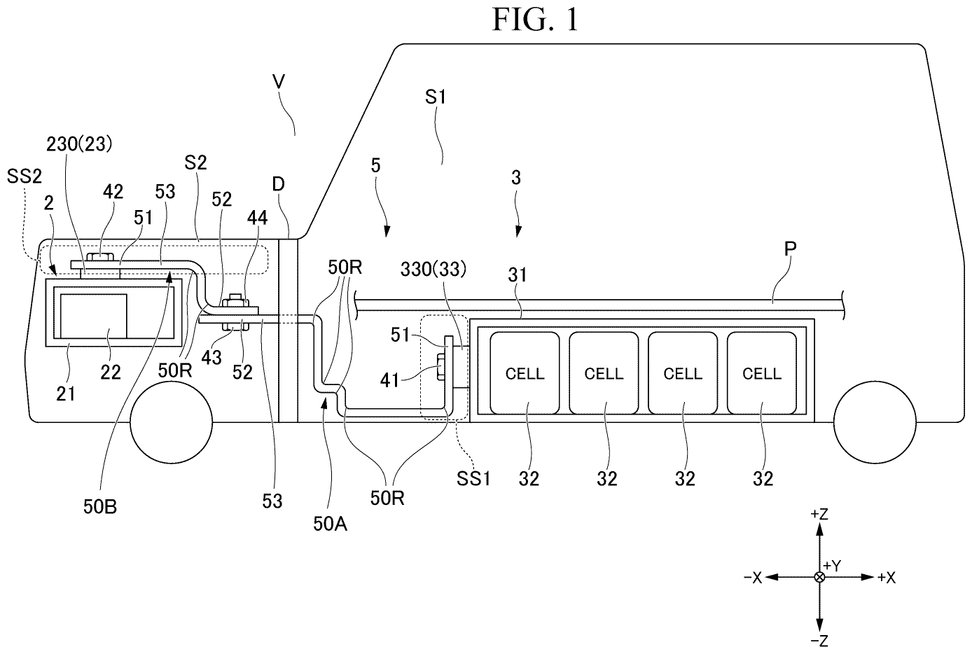

FIG. 1 is a diagram illustrating an example of a vehicle V including a routing structure. The vehicle V is an electric vehicle such as an electric vehicle (EV), a hybrid electric vehicle (HEV), or a plug-in hybrid electric vehicle (PHEV).

The vehicle V includes, for example, a frame body (not illustrated), a junction box 2, and a battery pack 3. The vehicle V is an example of a “structure”. The first routing structure 5 can be mounted on the vehicle V. The first routing structure 5 is an in-vehicle routing structure. The first routing structure 5 is an example of a “routing structure”.

The vehicle V has a space S1 and a space S2. The space S1 and the space S2 are roughly classified according to the vehicle body shape of the vehicle V. For example, when the frame body of the vehicle V is a monocoque body, a dash panel D is used as a boundary to roughly divide the space into the space S1 on the cabin side and the space S2 on the engine compartment side.

Further, the vehicle V has a space SS1 and a space SS2. The space SS1 is part of the space S1. The space SS2 is part of the space S2 or the space S1. The space SS1 is an example of a “first routing space”. The space SS2 is an example of a “second routing space”. Furthermore, an example in which the space SS2 is part of the space S1 will be described later as a modified example.

The space SS2 is located on one side of the vehicle V with respect to the space SS1. The space SS2 in the present embodiment is located on one side (+Z direction side) in the height direction of the vehicle V with respect to the space SS1.

In addition, the space SS1, for example, may be narrower than the space SS2.

In the present embodiment, the space SS1 is a small space defined by one or more of the shape of the frame body, the shape of the battery pack 3 mounted on the vehicle V, the shape of the panel member P forming the floor surface of the vehicle V, the shape of an object mounted on the vehicle V, and the like. In addition, the space SS1 is part of the space in the underfloor portion of the vehicle V in which a plurality of assembled batteries 32 (described later) are arranged.

The space SS2 in the present embodiment is a small space defined by one or more of the shape of the frame body, the shape of the junction box 2 mounted on the vehicle V, the shape of an object mounted on the vehicle V, and the like. The space SS2 in the present embodiment is part of the space S2 on the engine compartment side.

The first routing structure 5 is routed across the space SS1 and the space SS2.

Hereinafter, the connection target of the first routing structure 5 will be described.

First, the junction box 2 is a unit including a housing case 21, an in-vehicle device 22, and a second routing structure 23. The junction box 2 is an example of a “second unit”.

The in-vehicle device 22 is, for example, a connector, a fuse, a relay (for example, a mechanical relay or a semiconductor relay), a capacitor, a branching component, various sensors (for example, a current sensor or a voltage sensor), an electronic control unit, or an electronic component unit that combines two or more of these. The in-vehicle device 22 is electrically connected to the battery pack 3 by the first routing structure 5.

The housing case 21 is an outer shell member that forms most of the outer shape of the junction box 2. The shape of the housing case 21 varies depending on the arrangement of the in-vehicle device 22 and the routing of the second routing structure 23.

The in-vehicle device 22 is electrically connected to other connection components included in the junction box 2 by the second routing structure 23. The routing path of the second routing structure 23 is omitted for simplification of the drawing. The second routing structure 23 has a connection portion 230. For example, the connection portion 230 is used for power supply from the battery pack 3 to the in-vehicle device 22. The connection portion 230 in the present embodiment is exposed from the housing case 21, for example. The first routing structure 5 is connected to the connection portion 230.

The junction box 2 is disposed in the space S2. The junction box 2 is disposed on one side (for example, +Z direction side) of the vehicle V in the space S2. When the junction box 2 is disposed at the above position in the space S2, the connection portion 230 is disposed in the space SS2. The junction box 2 is disposed so as to be accessible from one side (for example, +Z direction side) of the vehicle V.

Next, the battery pack 3 is a unit including a housing case 31, a plurality of assembled batteries 32, and a third routing structure 33. The battery pack 3 is mounted on a frame body of the vehicle V. For example, the battery pack 3 is disposed on the other side (for example, on the −Z direction side,) in the height direction of the vehicle V with respect to the panel member P. In other words, the battery pack 3 is disposed in the underfloor portion of the vehicle V. The battery pack 3 is an example of a “first unit”.

The housing case 31 is an outer shell member that forms most of the outer shape of the battery pack 3. The shape of the housing case 31 varies depending on the arrangement of the plurality of assembled batteries 32 included in the battery pack 3 and the routing of the third routing structure 33.

Each of the plurality of assembled batteries 32 is electrically connected by the third routing structure 33. The routing path of the third routing structure 33 is omitted for simplification of the drawing. The third routing structure 33 has a connection portion 330. For example, the connection portion 330 is used for power supply from the battery pack 3 to the in-vehicle device 22. The connection portion 330 is exposed from, for example, the housing case 31, and the first routing structure 5 is connected to the connection portion 330.

The unit cell included in the assembled battery 32 is, for example, a nickel-metal hydride battery, a lithium ion battery, or other secondary batteries. The shape of the unit cell is not particularly limited. For example, the unit cell is not limited to a rectangular shape and may have a cylindrical shape.

When the battery pack 3 is disposed in the underfloor portion of the vehicle V in the space S1, the connection portion 330 is disposed in the space SS1. The battery pack 3 is disposed so as to be accessible from one side (for example, +Z direction side) of the vehicle V.

Here, one example of the reason why “space SS1 may be narrower than the space SS2” is that the space in the underfloor portion where the plurality of assembled batteries 32 are arranged tends to be narrower than the space S2 on the engine compartment side. For other reasons, “the space SS1 may be narrower than the space SS2”. Since “the space SS1 may be narrower than the space SS2”, a first routing member 50A to be described later may be required to have a bent portion in a more complex manner than a second routing member 50B.

The third routing structure 33 may further include a connection portion for charging the battery pack 3.

Each of the junction box 2 and the battery pack 3 is electrically connected to the first routing structure 5. The first routing structure 5 includes the first routing member 50A and the second routing member 50B. The first routing member 50A and the second routing member 50B are electrically connected to each other and form an electrical path from the battery pack 3 to the in-vehicle device 22. The first routing member 50A and the second routing member 50B are routing members through which a vehicle driving current flows. The first routing member 50A and the second routing member 50B have a conductor 57 and a fire-resistant insulating portion 58.

### Conductor

The conductor 57 forms an electrical path through which a current flows in the first routing structure 5. The conductor 57 is made of metal, for example. For example, the conductor 57 is made of aluminum, an aluminum alloy, copper, or a copper alloy. The conductor 57 is, for example, a member having a flat rectangular cross-sectional shape. The conductor 57 in the first routing member 50A is an example of a “first conductor portion”. The conductor 57 in the second routing member 50B is an example of a “second conductor portion”.

Hereinafter, when the first routing member 50A and the second routing member 50B are not distinguished from each other, they are simply referred to as “routing member 50”.

Here, a basic configuration of the routing member 50 will be described.

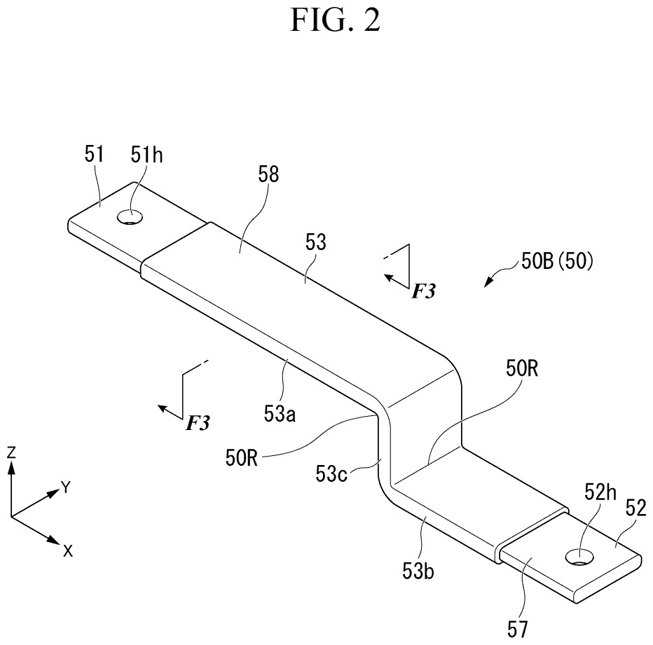

FIG. 2 is a perspective view illustrating an example of the routing member 50. The routing member 50 includes, for example, a first connection portion 51, a second connection portion 52, and an extension portion 53. In the present embodiment, each of the first connection portion 51, the second connection portion 52, and the extension portion 53 has a plate shape. That is, each of the first connection portion 51, the second connection portion 52, and the extension portion 53 has a flat rectangular cross-sectional shape. In FIG. 2, the second routing member 50B illustrated in FIG. 1 is illustrated as an example. The shape of the extension portion 53 is different between the first routing member 50A and the second routing member 50B in the present embodiment.

### First Connection Portion

The first connection portion 51 is a portion connected to the first connection target. The first connection target of the first routing member 50A is the battery pack 3 (see FIG. 1). The first connection target of the second routing member 50B is the junction box 2 (see FIG. 1). The first connection portion 51 is provided at one end of the routing member 50. The first connection portion 51 has an insertion hole 51h through which a fastening member 41 (for example, a bolt) or a fastening member 42 (for example, a bolt) passes.

### Second Connection Portion

The second connection portion 52 is a portion connected to the second connection target. The second connection target of the first routing member 50A is, for example, the second routing member 50B. Alternatively, the second connection target of the first routing member 50A may be another routing member that connects the first routing member 50A and the second routing member 50B. The second connection target of the second routing member 50B is, for example, the first routing member 50A. Alternatively, the second connection target of the second routing member 50B may be another routing member that connects the first routing member 50A and the second routing member 50B. The other routing member is not limited to the routing member 50.

In the present embodiment, the second connection target of the first routing member 50A is the second routing member 50B. The second connection target of the second routing member 50B is the first routing member 50A. The second connection portion 52 is provided at the other end of the routing member 50. The second connection portion 52 has an insertion hole 52h through which the fastening member 43 is passed.

### Extension Portion

The extension portion 53 is provided between the first connection portion 51 and the second connection portion 52. The extension portion 53 has, for example, a first extension portion 53a, a second extension portion 53b, and a third extension portion 53c.

The first extension portion 53a extends, for example, in the X direction along the horizontal direction. Similarly, the second extension portion 53b extends in the X direction along the horizontal direction, for example. The third extension portion 53c is provided between the first extension portion 53a and the second extension portion 53b and connects the first extension portion 53a and the second extension portion 53b. The third extension portion 53c extends, for example, along a direction intersecting the horizontal direction. The shape of the extension portion 53 is not limited to the above example. The extension portion 53, for example, may have only the first extension portion 53a and extend linearly, or may be bent more complexly.

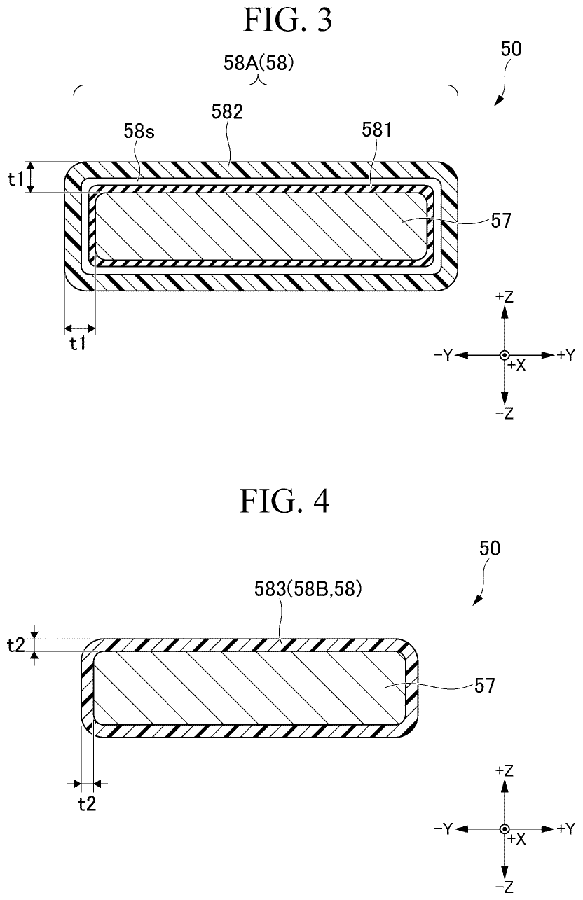

FIG. 3 is a cross-sectional view taken along line F3-F3 of the routing member 50 illustrated in FIG. 2.

The routing member 50 in the present disclosure has a fire-resistant structure by the fire-resistant insulating portion 58 described in detail below.

### Fire-Resistant Insulating Portion

The fire-resistant insulating portion 58 is a member having fire resistance that covers the outer periphery of the conductor 57. For example, when the conductor 57 has a flat rectangular cross-section, the fire-resistant insulating portion 58 covers the outer periphery of the conductor 57 so as to surround the entire periphery of the cross-section. The fire-resistant insulating portion 58 is provided in the extension portion 53 of the routing member 50 (see FIG. 2). On the other hand, the first connection portion 51 and the second connection portion 52 of the routing member 50 are not covered with the fire-resistant insulating portion 58 and are exposed to the outside of the routing member 50 (see FIG. 2).

When the extension portion 53 is bent, the routing member 50 has a bent portion 50R (see FIG. 2). The curvature radius (bending radius) of the bent portion 50R is defined by the curvature radius of the conductor 57 in the bent portion 50R and the curvature radius of the fire-resistant insulating portion 58 in the bent portion 50R.

Here, examples of the fire-resistant insulating portion 58 include a first type fire-resistant insulating portion 58A and a second type fire-resistant insulating portion 58B.

### Fire-Resistant Tape and Protective Member

The first type fire-resistant insulating portion 58A is illustrated in FIG. 3.

The fire-resistant insulating portion 58A includes a fire-resistant tape 581 and a protective member 582. The fire-resistant tape 581 is an insulating tape-shaped member wound around a peripheral surface of the conductor 57. For example, the fire-resistant tape 581 is a mica tape. The mica tape is a tape-shaped member containing mica having good insulation properties and fire resistance. Since the mica tape has a tape shape, the mica tape can closely contact the conductor 57. The protective member 582 serves to prevent fraying of the fire-resistant tape 581. The protective member 582 is a cylindrical molded product molded by injection-molding. The protective member 582 covers the outer periphery of the fire-resistant tape. As described above, since the protective member 582 is a molded product, the fire-resistant insulating portion 58A can have a gap 58s between the fire-resistant tape 581 and the protective member 582. The first type fire-resistant insulating portion 58A has a film thickness t1. The film thickness t1 indicates a thickness from the peripheral surface of the conductor 57 to the outer peripheral surface of the protective member 582 in the Z direction or the Y direction.

### Fire-Resistant Film

FIG. 4 is a cross-sectional view in a case where the routing member 50 illustrated in FIG. 3 includes the second type fire-resistant insulating portion 58B instead of the first type fire-resistant insulating portion 58A.

The fire-resistant insulating portion 58B includes an insulating fire-resistant film 583 covering the peripheral surface of the conductor 57. The fire-resistant film 583 includes a silicone resin and a fire-resistant filler. The fire-resistant filler in the present disclosure is a so-called fire-resistant inorganic filler and has a softening point higher than that of a silicone resin. The fire-resistant film 583 is integrated with the conductor 57. For example, a mixture of a silicone resin and a fire-resistant filler that have been kneaded is extruded together with the conductor 57 in an extruder, so that the mixture is integrated with the conductor 57. The fire-resistant film 583 integrated with the conductor 57 is molded along the outer periphery of the conductor 57 and has a rectangular cross-section. The second type fire-resistant insulating portion 58B has a film thickness t2. The film thickness t2 indicates a thickness from the peripheral surface of the conductor 57 to the outer peripheral surface of the fire-resistant film 583 in the Z direction or the Y direction.

In the present embodiment, the first routing member 50A includes, for example, a fire-resistant insulating portion 58A. The second routing member 50B includes, for example, a fire-resistant insulating portion 58B.

Hereinafter, the first routing member 50A and the second routing member 50B will be described separately.

First, the conductor 57 in the first routing member 50A and the conductor 57 in the second routing member 50B will be described separately. For example, in the first routing member 50A in the present embodiment, the conductor 57 is made of copper or a copper alloy. For example, in the second routing member 50B in the present embodiment, the conductor 57 is made of aluminum or an aluminum alloy. In the present disclosure, the conductor 57 made of aluminum or aluminum alloy has a smaller weight per unit length than the conductor 57 made of copper or copper alloy.

In addition, the conductor 57 made of copper or a copper alloy has larger toughness than the conductor 57 made of aluminum or an aluminum alloy. Therefore, the conductor 57 made of copper or copper alloy easily reduces the curvature radius of the bent portion 50R. In other words, the conductor 57 made of copper or copper alloy is easily bent as compared with the conductor 57 made of aluminum or aluminum alloy.

In the first routing member 50A of the present embodiment, the conductor 57 is made of copper or a copper alloy, so the first routing member 50A is bent in a more complex manner than the second routing member 50B (see FIG. 1). For example, X indicates the number of bent portions of the routing member 50 having the conductor 57 made of copper or copper alloy, and Y indicates the number of bent portions of the routing member 50 having the conductor 57 made of aluminum or aluminum alloy. In this case, X is larger than Y.

Here, the electrical conductivity of aluminum is about ⅗ of the electrical conductivity of copper, but the specific gravity of aluminum is about ⅓ of the specific gravity of copper. For example, in a case where the conductance of the copper conductor 57 and the conductance of the aluminum conductor 57 are substantially the same, a large cross-sectional area of the aluminum conductor 57 is required. The conductor 57 is formed by cutting out a metal strip. Since the thickness of the strip is limited depending on the type of metal, when the copper conductor 57 is replaced with the aluminum conductor 57, the dimension of the conductor 57 in the width direction tends to increase.

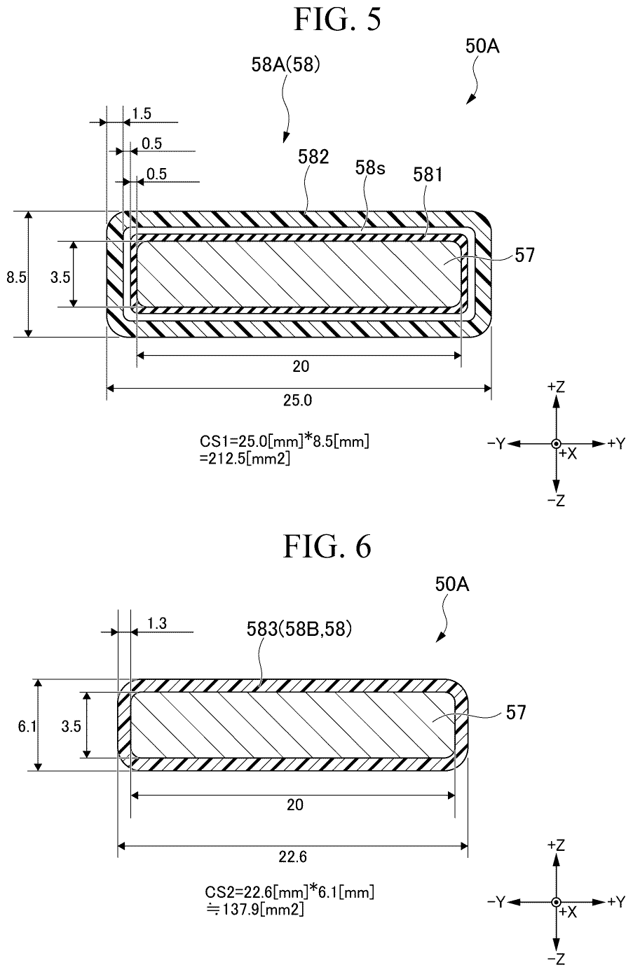

The first cross-section of the first routing member 50A having the copper or copper alloy conductor 57 is illustrated in FIGS. 5 and 6. The first cross-section is orthogonal to the extension direction of the extension portion 53 of the first routing member 50A. FIG. 5 illustrates a first cross-section of the first routing member 50A having the first type fire-resistant insulating portion 58A. FIG. 6 illustrates a first cross-section of the first routing member 50A having the second type fire-resistant insulating portion 58B. The type (first type, second type) of the fire-resistant insulating portion 58 is different between FIG. 5 and FIG. 6.

The conductor 57 of the first routing member 50A in the present embodiment is made by cutting out, for example, a copper or copper alloy strip having a thickness of 3.5 mm. The cross-sectional area of the conductor 57 of the first routing member 50A is, for example, 70 mm². In the present embodiment, the thickness (film thickness t1) of the fire-resistant insulating portion 58A is 2.5 mm in total, which is the thickness of the fire-resistant tape 581:0.5 mm, the gap 58s: 0.5 mm, and the thickness of the protective member 582:1.5 mm. In the present embodiment, the thickness of the fire-resistant film 583 (film thickness t2) is 1.3 mm in total, which is the thickness of the fire-resistant film 583 being 1.3 mm. From FIGS. 5 and 6, the thickness (film thickness t2) of the second type fire-resistant insulating portion 58B is thinner than the thickness (film thickness t1) of the fire-resistant insulating portion 58A. When the first routing member 50A has the fire-resistant insulating portion 58B instead of the fire-resistant insulating portion 58A, the cross-sectional area of the first routing member 50A in the first cross-section is reduced from the cross-sectional area CS1 of 212.5 mm² to the cross-sectional area CS2 of 137.9 mm². The cross-sectional area CS1 is expressed by a product of a thickness of 8.5 mm in the Z direction and a width of 26.0 mm in the Y direction of the first routing member 50A having the fire-resistant insulating portion 58A. The cross-sectional area CS2 is expressed by a product of a thickness of 6.1 mm in the Z direction and a width of 22.6 mm in the Y direction of the first routing member 50A having the fire-resistant insulating portion 58B.

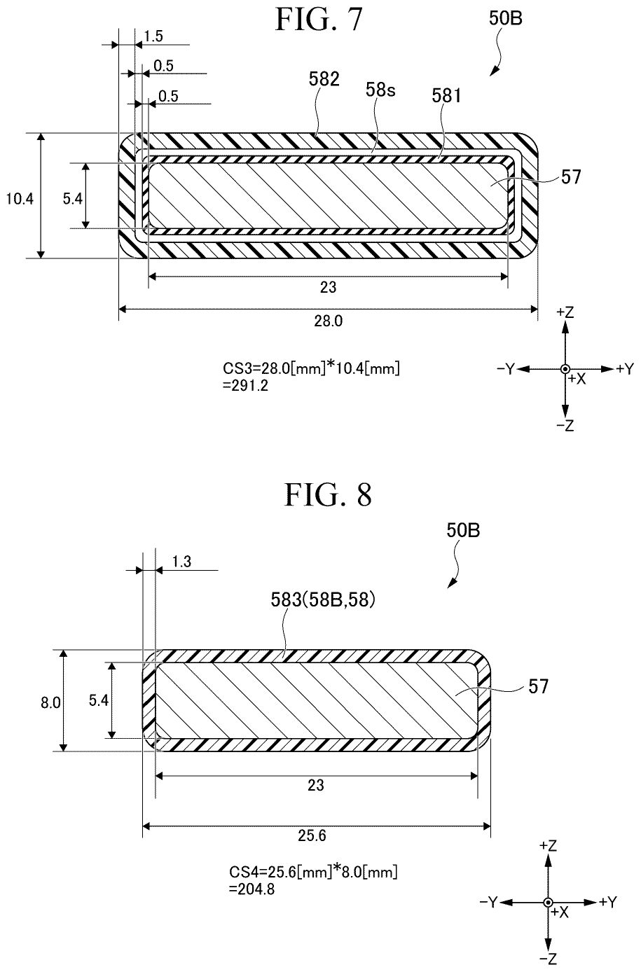

A second cross-section of the second routing member 50B having the conductor 57 made of aluminum or an aluminum alloy is illustrated in FIGS. 7 and 8. The second cross-section is orthogonal to the extension direction of the extension portion 53 of the second routing member 50B. FIG. 7 illustrates a second cross-section of the second routing member 50B having the first type fire-resistant insulating portion 58A. FIG. 8 illustrates a second cross-section of the second routing member 50B having the second type fire-resistant insulating portion 58B. The type (first type, second type) of the fire-resistant insulating portion 58 is different between FIG. 7 and FIG. 8.

The conductor 57 of the second routing member 50B in the present embodiment is formed, for example, by cutting out a strip made of aluminum or an aluminum alloy having a thickness of 5.4 mm. The cross-sectional area of the conductor 57 of the second routing member 50B is, for example, 125 mm². In the present embodiment, the thickness (film thickness t1) of the fire-resistant insulating portion 58A is 2.5 mm in total, which is the thickness of the fire-resistant tape 581:0.5 mm, the gap 58s: 0.5 mm, and the thickness of the protective member 582:1.5 mm. In the present embodiment, the thickness of the fire-resistant film 583 (film thickness t2) is 1.3 mm in total, which is the thickness of the fire-resistant film 583 being 1.3 mm. From FIGS. 7 and 8, the thickness (film thickness t2) of the second type fire-resistant insulating portion 58B is thinner than the thickness (film thickness t1) of the fire-resistant insulating portion 58A. When the second routing member 50B includes the fire-resistant insulating portion 58B instead of the fire-resistant insulating portion 58A, the cross-sectional area of the second routing member 50B in the second cross-section is reduced from 291.2 mm² of the cross-sectional area CS3 to 204.8 mm² of the cross-sectional area CS4. The cross-sectional area CS3 is expressed by a product of a thickness of 10.4 mm in the Z direction and a width of 28.0 mm in the Y direction of the second routing member 50B having the fire-resistant insulating portion 58A. The cross-sectional area CS4 is expressed by a product of a thickness of 8.0 mm in the Z direction and a width of 25.6 mm in the Y direction of the second routing member 50B having the fire-resistant insulating portion 58B.

For example, the magnitude relationship of each cross-sectional area (cross-sectional areas CS1, CS2, CS3, CS4) described above is as follows.

CS3>CS1>CS4>CS2

The thickness of the first routing member 50A in the Z direction in the first cross-section is 9.5 mm. The thickness of the second routing member 50B in the Z direction in the second cross-section is 8.0 mm. Therefore, in the present embodiment, the thickness of the second routing member 50B in the second cross-section is smaller than the thickness of the first routing member 50A in the first cross-section (see FIGS. 5 and 6).

From FIGS. 5 and 7, the cross-sectional area of the conductor 57 made of aluminum or aluminum alloy in the second cross-section is larger than the cross-sectional area of the conductor 57 made of copper or copper alloy in the first cross-section. Similarly, from FIGS. 6 and 8, the cross-sectional area of the conductor 57 made of aluminum or aluminum alloy in the second cross-section is larger than the cross-sectional area of the conductor 57 made of copper or copper alloy in the first cross-section.

As illustrated in FIG. 1 again, the first routing member 50A in the present embodiment has a larger number of bends per unit length than the second routing member 50B. The first routing member 50A has, for example, four bent portions 50R. The second routing member 50B has, for example, two bent portions 50R.

Here, the curvature radius (bending radius) of the bent portion 50R of the routing member 50 will be described.

The routing member 50 having the fire-resistant insulating portion 58A has advantages in terms of routing in that the manufacturing method is different from that of the routing member 50 having the fire-resistant insulating portion 58B. In the routing member 50 having the fire-resistant insulating portion 58A, the conductor 57 obtained by punching the strip with a press is bent and formed into a predetermined shape. Next, the mica tape is wound around the molded conductor 57. Finally, a protective member that serves to prevent fraying of the mica tape is attached to the conductor 57 around which the mica tape is wound. That is, in the routing member 50 having the fire-resistant insulating portion 58A, the presence of the protective member 582 is less likely to affect the bending of the conductor 57.

On the other hand, in the routing member 50 having the fire-resistant insulating portion 58B, a mixture of silicone resin and fire-resistant filler is provided by extrusion processing on the conductor 57 obtained by punching out a strip with a press. Next, the extruded conductor 57 is bent and formed into a predetermined shape. When the conductor 57 subjected to the extrusion process is bent, an internal force resisting bending is generated by the silicone resin. That is, in the routing member 50 having the fire-resistant insulating portion 58B, the presence of the fire-resistant insulating portion 58B affects the bending of the conductor 57, and the bent portion 50R of the routing member 50 may become large.

As described above, in the present embodiment, the curvature radius of the bent portion 50R in the first routing member 50A is smaller than the curvature radius of the bent portion 50R in the second routing member 50B (see FIG. 1).

Next, the arrangement of the first routing member 50A and the second routing member 50B in the vehicle V will be described.

### First Routing Member 50A

As illustrated in FIG. 1 again, the first routing member 50A is provided between the battery pack 3 and the second routing member 50B and electrically connects the battery pack 3 and the second routing member 50B. As described above, the first routing member 50A is arranged in the space SS1 narrower than the space SS2.

The first routing member 50A is electrically connected to the battery pack 3 which is the “first unit”. For example, in the first routing member 50A, the fastening member 41 (for example, screw) passes through the insertion hole 51h of the first connection portion 51, and the battery pack 3 and the first routing member 50A are electrically connected.

### Second Routing Member 50B

The second routing member 50B is disposed in the space SS2.

The second routing member 50B is electrically connected to the junction box 2 which is a “second unit”. For example, in the second routing member 50B, the fastening member 42 (for example, screw) passes through the insertion hole 51h of the first connection portion 51, and the junction box 2 including the in-vehicle device 22 and the second routing member 50B are electrically connected.

In the present embodiment, the first routing member 50A and the second routing member 50B are directly connected to each other without interposing another routing member therebetween. For example, the second connection portion 52 of the first routing member 50A and the second connection portion 52 of the second routing member 50B are electrically connected to each other by a fastening member 43 (for example, screw or bolt) passing through the insertion hole 52h of each of the second connection portions 52. The fastening member 43 in the present embodiment is a rivet bolt, and the second routing member 50B and the first routing member 50A are joined by engaging an engaging member 44 (for example, nut) with the fastening member 43. Joining of the second routing member 50B and the first routing member 50A is not limited to joining by fastening means. For example, the second routing member 50B and the first routing member 50A may be joined by laser welding, resistance welding, ultrasonic welding, or friction stir welding.

### Advantages

In the present embodiment, the routing structure (for example, the first routing structure 5) is an in-vehicle routing structure. The routing structure includes the first routing member 50A and the second routing member 50B. The first routing member 50A includes the first conductor portion (for example, the conductor 57) made of copper or a copper alloy and the first fire-resistant insulating portion (for example, the fire-resistant insulating portion 58A) covering an outer periphery of the first conductor portion. The second routing member 50B includes the second conductor portion (for example, the conductor 57) made of aluminum or aluminum alloy and the second fire-resistant insulating portion (for example, the fire-resistant insulating portion 58B) covering the outer periphery of the second conductor portion. The second routing member 50B is electrically connected to the first routing member 50A.

According to such a configuration, the routing structure includes the first routing member 50A including the first conductor portion made of copper or a copper alloy and the second routing member 50B including the second conductor portion made of aluminum or an aluminum alloy. With this configuration, weight reduction can be achieved when the routing structure (first routing structure 5) is viewed as a whole.

When the second routing member 50B including the second conductor portion made of aluminum or aluminum alloy is adopted as part of the routing structure, cost reduction of the routing structure may be achieved.

According to another aspect, since the routing structure includes the first routing member 50A including the conductor 57 having toughness larger than that of the second routing member 50B and the second routing member 50B, the number of bent portions can be made different (the shapes can be made different) between the two routing members 50. In the above-described routing structure, the two routing members 50 can be selectively used for a narrow space.

In the present embodiment, the cross-sectional area of the second conductor portion in the second cross-section orthogonal to the extension direction of the second routing member 50B is larger than the cross-sectional area of the first conductor portion in the first cross-section orthogonal to the extension direction of the first routing member 50A. The second routing member 50B is arranged in the second routing space (for example, space SS2). The first routing member 50A is arranged in the first routing space (for example, the space SS1) narrower than the second routing space.

According to such a configuration, when the cross-sectional area of the second conductor portion can be increased by being made of aluminum or an aluminum alloy, the routing structure disposes the second routing member 50B in the second routing space. Here, since the routing structure includes the first routing member 50A including the conductor 57 having higher toughness than the second routing member 50B, the first routing member 50A in the routing structure can be arranged in the first routing space narrower than the second routing space. Therefore, in the above-described routing structure, the two routing members 50 can be selectively used for a narrow space.

In the present embodiment, the first routing member 50A and the second routing member 50B are routing members that are electrically connected to each other and through which a vehicle driving current flows. According to such a configuration, it is possible to reduce the weight of the vehicle V on which the routing structure (first routing structure 5) is mounted.

In the present embodiment, the first routing member 50A is provided between the battery pack 3 and the second routing member 50B and electrically connects the battery pack and the second routing member 50B. According to such a configuration, the first routing member 50A having a thickness larger than that of the second routing member 50B can be arranged around the battery pack 3. It is possible to suppress an inadvertent shift in higher position of the center of gravity of the vehicle V on which the routing structure (first routing structure 5) is mounted.

### Modified Examples

Next, several modified examples of the embodiment will be described. Furthermore, a configuration other than that described below in each modified example is the same as the configuration of the above embodiment.

### First Modified Example

In the above-described routing structure (first routing structure 5) of the present disclosure, the type of metal of the conductor 57 in the first routing member 50A and the type of metal of the conductor 57 in the second routing member 50B may be different from each other. Therefore, the type of the fire-resistant insulating portion 58 included in each of the two routing members 50 is not limited. In the present modified example, for example, both the first fire-resistant insulating portion and the second fire-resistant insulating portion may be the fire-resistant insulating portion 58A. For example, instead of the above example, both the first fire-resistant insulating portion and the second fire-resistant insulating portion may be the fire-resistant insulating portion 58B. In a case where each of the two routing members 50 has the second fire-resistant insulating portion 58B, the fire-resistant film 583 reduces the thickness of each of the two routing members 50. Since the routing structure includes the first routing member 50A and the second routing member 50B each including the fire-resistant film 583, the routing structure (first routing structure 5) can be downsized.

### Second Modified Example

From the same viewpoint as in the first modified example, the following configuration may be adopted in the routing structure.

In the present modified example, the conductor 57 of the first routing member 50A is made of copper or a copper alloy, and the first routing member 50A has the fire-resistant insulating portion 58B. The conductor 57 of the second routing member 50B is made of aluminum or aluminum alloy and the second routing member 50B has the fire-resistant insulating portion 58A.

### Third Modified Example

For example, the junction box 2 may be disposed in the space S1. The space SS2 in the present modified example is part of the space S1. The junction box 2 may be mounted on the battery pack 3. The junction box 2 is detachably fixed to the battery pack 3 at the time of maintenance. In the present modified example, the conductor 57 of the second routing member 50B is preferably made of aluminum or an aluminum alloy.

According to such a configuration, it is easy to detach the junction box 2 to which the conductor 57 made of aluminum or aluminum alloy is connected. Furthermore, the second routing member 50B can be transported in a state of being connected to the junction box 2.

The space SS2 in the third modified example is defined by one or more of the shape of the frame body, the shape of the battery pack 3 mounted on the vehicle V, the shape of the panel member P forming the floor surface of the vehicle V, the shape of an object mounted on the vehicle V, and the like. The space SS2 in the third modified example is located on one side (+Z direction side) in the height direction of the vehicle V with respect to the space SS1. Here, it is difficult for all of these shapes defining the space SS2 to have a size extending from one end to the other end of the underfloor portion in the height direction of the vehicle V. Therefore, also in the third modified example, the space SS1 is narrower than the space SS2.

### Fourth Modified Example

For example, the housing case 31 of the battery pack 3 may contain the junction box 2. The space SS2 and the space SS1 in the fourth modified example are provided in the housing case 31. The space SS2 in the fourth modified example is located on one side (for example, one side in the horizontal direction) of the vehicle V with respect to the space SS1.

### Fifth Modified Example

The connection portion 230 may be contained in the housing case 21, for example. The first routing member 50A of the first routing structure 5 is connected to the included connection portion 230.

### Sixth Modified Example

The connection portion 330 may be contained in the housing case 31, for example. The second routing member 50B of the first routing structure 5 is connected to the included connection portion 330.

### Seventh Modified Example

When the thicknesses of the conductors 57 in the two routing members 50 are substantially the same regardless of the type of metal, the cross-sectional areas of the first conductor portion and the second conductor portion may be the same.

As described above, the embodiment and the modified examples have been described. However, the embodiment and the modified examples are not limited to the examples described above. For example, the plurality of modified examples described above may be implemented in combination with each other. The above-described embodiment can be implemented in various other forms, and various additions, omissions, substitutions, and modifications can be implemented without departing from the gist of the disclosure.

### INDUSTRIAL APPLICABILITY

In accordance with an embodiment of the present disclosure, it is possible to reduce the weight of the routing structure.

### REFERENCE SIGNS LIST

V vehicle (structure)
D Dash panel
2 Junction box (second unit)
21 Housing case
22 In-vehicle device
23 Second routing structure
230 Connection portion
3 Battery pack (first unit)
31 Housing case
32 Assembled battery
33 Third routing structure
330 Connection portion
41 Fastening member
42 Fastening member
43 Fastening member
44 Engaging member
5 First routing structure (Routing structure)
50 Routing member
50A First routing member
50B Second routing member
50R Bent portion
51 First connection portion
51h Insertion hole
52 Second connection portion
52h Insertion hole
53 Extending portion
53a First extension portion
53b Second extension portion
53c Third extension portion
57 Conductor (first conductor portion and second conductor portion)
58 Fire-resistant insulating portion
58A Fire-resistant insulating portion
581 Fire-resistant tape
58s Gap
582 Protective member
58B Fire-resistant insulating portion
583 Fire-resistant film
CS1, CS2, CS3, CS4 Cross-sectional area
S1 Space
S2 Space
SS1 Space (first routing space)
SS2 Space (second routing space)
t1 Film thickness
t2 Film thickness

What is claimed is:

1. An in-vehicle routing structure comprising:
a first routing member including a first conductor portion made of copper or a copper alloy and a first fire-resistant insulating portion covering an outer periphery of the first conductor portion;
a second routing member including a second conductor portion made of aluminum or an aluminum alloy and a second fire-resistant insulating portion covering an outer periphery of the second conductor portion and electrically connected to the first routing member.

2. The routing structure according to claim 1, wherein
a cross-sectional area of the second conductor portion in a second cross-section orthogonal to an extension direction of the second routing member is larger than a cross-sectional area of the first conductor portion in a first cross-section orthogonal to an extension direction of the first routing member,
the second routing member is disposed in a second routing space, and
the first routing member is disposed in a first routing space narrower than the second routing space.

3. The routing structure according to claim 1, wherein
the first fire-resistant insulating portion is an insulating fire-resistant film covering a peripheral surface of the first conductor portion, and
the second fire-resistant insulating portion is an insulating fire-resistant film covering a peripheral surface of the second conductor portion.

4. The routing structure according to claim 1, wherein
the routing structure is mountable on a structure including a first unit and a second unit detachable from the first unit,
the second routing member has a smaller weight per unit length than the first routing member,
the first routing member is connected to the first unit, and
the second routing member is connected to the second unit.

5. The routing structure according to claim 4,
wherein the second unit is a unit to be detached from the first unit during maintenance.
